(19) United States
(12) Patent Application Publication
(10) Pub. No.: US 2002/0109200 A1
(43) Pub. Date: Aug. 15, 2002

(54) Semiconductor product with a Schottky contact

(76) Inventors: Wolfgang Bartsch, Erlangen (DE); Heinz Mitlehner, Uttenreuth (DE)

Correspondence Address: WERNER AND GREENBERG P.A., Post Office Box 2480, Hollywood, FL, 33022-2480, US

(21) Appl. No.: 10/068,726

(22) Filed: Feb. 6, 2002

Related U.S. Application Data
(63) Continuation of application No. PCT/DE00/02584, filed on Aug. 2, 2000.

(30) Foreign Application Priority Data
Aug. 6, 1999 (DE) 199 37 198.9

(51) Int. Cl. H01L 31/108; H01L 31/07; H01L 29/812; H01L 29/47; H01L 27/095

(52) U.S. Cl. 257/471

(57) ABSTRACT

A semiconductor product is described that contains a semiconducting body doped with a first conductivity type, a Schottky contact layer disposed on the semiconducting body and forms a Schottky contact with the semiconducting body, an ohmic contact layer disposed adjacent the Schottky contact layer, and a diode structure disposed laterally beside the Schottky contact. The diode structure has a first region disposed in the semiconducting body. The first region is doped with a second conductivity type and is connected to the Schottky contact layer through the ohmic contact layer. The diode structure has a second region functioning as part of an edge termination and surrounds the Schottky contact and the first region. The second region is disposed in the semiconducting body and is doped with the second conductivity type.

### CROSS-REFERENCE TO RELATED APPLICATION

This application is a continuation of copending International Application PCT/DE00/02584, filed Aug. 2, 2000, which designated the United States.

### BACKGROUND OF THE INVENTION

### FIELD OF THE INVENTION

The application relates to a semiconductor product containing a semiconducting body, which is doped with a first conductivity type and on which a Schottky contact layer is applied, which forms a Schottky contact with the semiconducting body.

Such a semiconductor product is described in International Patent Disclosure WO 96/03774 A1, see, in particular, FIG. 2 together with the associated description. The semiconductor product is a Schottky diode for application in the case of a high reverse voltage and a high reverse current. It contains an edge region that surrounds the actual Schottky contact and is formed by special doping in the body, in order to avoid, at the actual Schottky contact, the production of an excessively high electric field that could considerably impair the dielectric strength of the semiconductor body.

The prior art to be taken into account in the present case furthermore emerges from Published, European Patent Application EP 0 380 340 A2, U.S. Pat. No. 4,157,563 and Published, Non-Prosecuted German Pat. DE 38 32 748 A1. Except for the U.S. patent, these documents relate, in particular, in each case to a Schottky diode, realized in semiconducting silicon carbide, a semiconductor distinguished by a particularly high band gap and further positive properties.

Also of importance are the books titled “Power Semiconductor Devices”, by B. J. Baliga, PWS Publishing Company, Boston, USA, 1995, see, in particular, Chapter 4 and Section 4.3, page 182 et seq. therein, where a Schottky diode is described which additionally contains structures in the manner of a pn diode in order to improve its dielectric strength, and “Modern Power Devices” by B. J. Baliga, Krieger Publishing Company, Malabar, Florida, USA, 1992, in particular Chapter 3.6, page 79 et seq., which reveals indications for configuring an edge termination for a semiconductor product having a particularly high dielectric strength.

Indications on the function of an edge termination of the type described in a Schottky diode having a high dielectric strength can also be found in the book titled “Metal-Semiconductor Contacts” by E. H. Rhoderick and R. H. Williams, second edition, Clarendon, Oxford, UK, 1988, see, in particular, the figure on page 131 together with the associated description.

With regard to all the documents cited above, it should be emphasized that, in respect of the concrete configuration of a semiconductor product, the documents only ever refer to the problem area of ensuring a sufficient reverse voltage strength.

Further embodiments of a Schottky diode are described in Published European Patent EP 0 803 913 A 1, the English-language abstract to Japanese Patent JP 10-116999 A and the English-language abstract to Japanese Patent JP 60-128675 A. In these embodiments, a p-conducting region is in each case disposed within an n-conducting body laterally beside a region in which the n-conducting body forms a Schottky contact with a contact layer, the p-conducting region likewise being at least partly covered by the conduct layer.

U.S. Pat. No. 5,789,911 discloses a method for fabricating a Schottky diode made of n-conducting silicon carbide. The n-conducting silicon carbide body forms a pn junction with a p-conducting silicon carbide layer disposed at its surface. A Schottky diode made of silicon carbide is increasingly of interest for application in a high-power switching installation or a switched-mode power supply. However, in such an application, a Schottky diode is subjected not only to a high reverse voltage loading but also, at least occasionally, to a very high loading by current which traverses the Schottky diode in the forward direction. In particular when a storage capacitor is to be charged for the first time via the Schottky diode, it must be expected that a current which exceeds a rated current, for which the diode is actually configured, by a large multiple will flow through the diode. Such a “surge current” may be more than a hundred times the rated current, which is not usually exceeded in the context of regular operation. Accordingly, a functionally conforming configuration of a Schottky diode should also take account of the possibility of the occasional overloading by a surge current that substantially exceeds the rated current. However, a corresponding consideration cannot be gathered from the present prior art.

### SUMMARY OF THE INVENTION

It is accordingly an object of the invention to provide a semiconductor product with a Schottky contact that overcomes the above-mentioned disadvantages of the prior art devices of this general type, provided, in accordance with the invention, in which a current which is of the magnitude of a predetermined surge current and momentarily overloads the semiconductor product is conducted through in a controlled manner.

With the foregoing and other objects in view there is provided, in accordance with the invention, a semiconductor product. The semiconductor product contains a semiconducting body doped with a first conductivity type, a Schottky contact layer disposed on the semiconducting body and forms a Schottky contact with the semiconducting body, an ohmic contact layer disposed adjacent the Schottky contact layer, and a diode structure disposed laterally beside the Schottky contact. The diode structure has a first region disposed in the semiconducting body. The first region is doped with a second conductivity type and is connected to the Schottky contact layer through the ohmic contact layer. The diode structure has a second region functioning as part of an edge termination and surrounds the Schottky contact and the first region. The second region is disposed in the semiconducting body and is doped with the second conductivity type.

In order to achieve the object, what is specified is a semiconductor product containing the semiconducting body, which is doped with a first conductivity type and on which the Schottky contact layer is applied, which forms the Schottky contact with the body. There is disposed laterally beside the Schottky contact a diode structure containing the first region in the body. The first region is doped with a second conductivity type and is connected to the Schottky contact layer via the ohmic contact layer. The Schottky contact and the first region are surrounded by the edge termination containing the second region in the body, the second region is doped with the second conductivity type.

Accordingly, a pn diode connected in parallel with the Schottky contact is provided in the semiconductor product. In principle, the pn diode has a higher threshold voltage than the Schottky contact and is thus deactivated during operation of the product with a through-flowing current having a low magnitude as configured. If a current which overloads the Schottky contact flows, then the voltage drop produced across the Schottky contact increases on account of the inherent positive temperature coefficient and, when the threshold voltage of the pn diode is exceeded, puts the pn diode into its conducting state. Thus, the loading on the Schottky contact is relieved and, the flow of the overloading current is controlled—it remains restricted to the pn diode that, on account of its inherent negative temperature coefficient accepts the overloading current to an increasing extent from the Schottky contact.

What is thus avoided, in particular, is the situation in which, in the event of loading in accordance with the surge current, the semiconductor product is heated in an uncontrolled and unpredictable manner and possible causes damage, not only to itself but also to a circuit in which it is incorporated. The semiconductor product unites in itself the positive properties of a Schottky diode during regular operation and the positive properties of a pn diode during momentary overloading.

By virtue of the fact that the Schottky contact and the first region are surrounded by the edge termination containing the second region in the body. The second region being doped with the second conductivity type, the product additionally acquires a predeterminable dielectric strength.

The Schottky contact layer contains a metal that is to be specifically selected depending on the type of semiconducting body and its doping. For an n-conductively doped body made of silicon carbide, in particular titanium, tantalum, chromium and nickel are appropriate for the metal. The thickness of the Schottky contact layer may generally remain small; a typical thickness is 150 nm.

Preferably, the first region reaches down to a first depth into the body, which first depth is greater than a second depth, down to which the second region reaches into the body.

This ensures that a current that overloads the product and penetrates into the first region does not reach the second region; moreover, this prevents a detrimentally strong electric field from forming at the second region.

It is furthermore preferable for the first region to be doped inhomogeneously with a doping density that has a maximum at the ohmic contact. This ensures particularly good contact connection of the pn diode connected in parallel with the Schottky contact. It should be noted that a corresponding doping density results largely automatically if, for a body composed of a silicon carbide, aluminum is used both for the doping of the first region and for forming the ohmic contact layer—the doping density can be achieved by interdiffusion between the contact layer and the body.

Particular preference is attached to a configuration of the semiconductor product in which the first region surrounds the Schottky contact; a pn diode having a particularly high loading capacity is achieved as a result.

The body of the semiconductor product is preferably divided into an epitaxial layer adjoining the Schottky contact and a substrate which is remote from the Schottky contact and is doped more heavily than the layer. In this way, the layer with its relatively low doping ensures a high blocking capability and the substrate with its relatively high doping ensures a relatively low contact resistance of the semiconductor product. The substrate may be, in particular, part of a semiconductor wafer cut from a bulk crystal. The substrate is furthermore preferably contact-connected with an ohmic contact, so that the Schottky contact layer and the ohmic contact constitute the connections of the semiconductor product for incorporation into an external circuit.

The substrate of the semiconductor product is particularly preferably a crystal made of silicon carbide. Silicon carbide as a semiconductor with a high band gap has the additional advantage in the present case that the pn diode provided besides the Schottky diode begins to conduct only at a comparatively high voltage and, accordingly, practically does not impair the function of the Schottky contact during regular operation.

The Schottky contact layer of the semiconductor product is preferably covered with a conductive contact reinforcing layer, in particular formed from a correspondingly customary metal such as aluminum. The contact reinforcing layer facilitates the contact connection of the Schottky contact layer by bonding, soldering, clamping and other customary contact connections. The contact reinforcing layer preferably connects the Schottky contact layer to the ohmic contact layer.

Other features which are considered as characteristic for the invention are set forth in the appended claims.

Although the invention is illustrated and described herein as embodied in a semiconductor product with a Schottky contact, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, sectional view of an exemplary embodiment of a semiconductor product according to the invention; and

FIG. 2 is a sectional view of a second embodiment of the semiconductor product.

### DESCRIPTION OF THE PREFERRED EMBODIMENTS

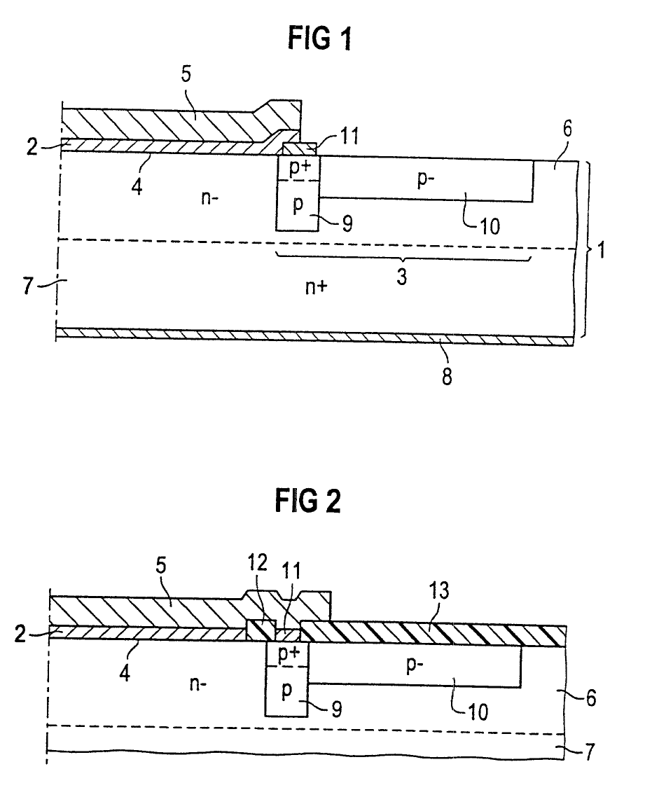

In all the figures of the drawing, sub-features and integral parts that correspond to one another bear the same reference symbol in each case. Referring now to the figures of the drawing in detail and first, particularly, to FIG. 1 thereof, there is shown a semiconductor product containing a body 1 made of a semiconductor, to be precise n-conductively doped silicon carbide, and a Schottky contact layer 2 applied thereon. The Schottky contact layer 2 contains a layer made of titanium having a thickness of about 150 nm and forms, with the body 1, a Schottky contact 4 which is surrounded and bordered by an edge region 3. The Schottky contact layer 2 is covered by a contact reinforcing layer 5 made of aluminum for improving the thermal and electrical contact connection of the Schottky contact layer 2. The body 1 is divided into an epitaxial layer 6 facing the Schottky contact 4 and a substrate 7 that is remote from the Schottky contact 4 and is doped more heavily than the layer 6 grown thereon. The relatively low doping of the layer 6 ensures a high blocking capability and the relatively high doping of the substrate 7 ensures a low forward resistance of the semiconductor product. Also situated on the substrate 7 is an ohmic contact 8 made of a conventional metal, which serves as the cathode of the semiconductor product. The anode of the semiconductor product is provided by the Schottky contact layer 2 and the contact reinforcing layer 5. The edge region 3 of the semiconductor product contains a first region 9 that directly faces the Schottky contact 4 and a second region 10 that is remote from the Schottky contact 4. The first region 9 is at least partly doped more heavily than the second region 10 and also extends more deeply into the substrate 1; it forms with the substrate 1 a pn diode which, in the event of overloading of the semiconductor product with a through-flowing current, accepts part of the overloading current and relieves the loading on the Schottky contact 4. For reliable contact connection to an ohmic contact layer 11, a relatively high doping of the first region 9 is required in the vicinity of the ohmic contact layer 11, as indicated by the symbol “p+”. The first region 9 is connected to the Schottky contact layer 2 via the ohmic contact layer 11; it is functionally unimportant that in the present case the Schottky contact layer 2 also makes direct contact with the first region 9.

FIG. 2 shows a development of the exemplary embodiment in accordance with FIG. 1. In this case, it is provided that the Schottky contact layer 2 and the ohmic contact layer 11 are spaced apart from one another by a first insulating layer 12 and their electrical connection is provided via the correspondingly extended contact reinforcing layer 5. Also provided is a second insulating layer 13, which serves for the passivation of the semiconductor product outside the region of the Schottky contact 4.

The concrete configuration of a real semiconductor product in accordance with one of the exemplary embodiments outlined generally requires the application of the simulation technology which is familiar to the person skilled in the relevant art, in order to select and match to one another the dimensions and further characteristic quantities of all the constituent parts of the semiconductor product.

An exemplary embodiment which is considered in concrete terms for production is configured for a regular current of about 4 amperes and is intended to be able to conduct momentarily, typically for a time period of 10 microseconds, an average surge current of 120 amperes in the manner described. An averaged surge current of 60 amperes is taken into consideration for a longer time period of 3 milliseconds. The Schottky contact 4 is circular with a diameter of 1.4 millimeters. The annularly configured first region 9 that directly adjoins the Schottky contact 4 has a width of about 100 and 150 micrometers. The threshold voltage of the Schottky contact 4 is about 1 volt; the threshold voltage of the pn diode is between 2.4 volts and 3 volts. Functionally, the electrical voltage arising across the semiconductor product, in the event of overloading, is limited by the pn diode, which becomes conductive, to a value of between 2.4volts and 3 volts. The blocking capability of the semiconductor product is in no way impaired by the configuration with regard to the surge current, because the conventional devices such as specially doped rings in the manner of the second region 10 and field plates are available; in this respect, see the cited prior art. The exemplary embodiment that is considered in concrete terms is dimensioned for a reverse voltage of 600 V; to that end, the second region 10 requires a width of about 40 micrometers. The semiconductor product is to be incorporated into a conventional housing of the TO 220 type.

The invention makes it possible to realize a Schottky diode which has particularly favorable properties both with regard to its blocking capability and with regard to its overloading capacity by a surge current.

We claim:

1. A semiconductor product, comprising:
a semiconducting body doped with a first conductivity type;
a Schottky contact layer disposed on said semiconducting body and forming a Schottky contact with said semiconducting body;
an ohmic contact layer disposed adjacent said Schottky contact layer; and
a diode structure disposed laterally beside said Schottky contact, said diode structure having a first region disposed in said semiconducting body, said first region being doped with a second conductivity type and connected to said Schottky contact layer through said ohmic contact layer, said diode structure having a second region functioning as part of an edge termination and surrounding said Schottky contact and said first region, said second region disposed in said semiconducting body and doped with said second conductivity type.

2. The semiconductor product according to claim 1, wherein said first region reaches down to a first depth into said semiconducting body, said first depth is greater than a second depth, down to which said second region reaches into said semiconducting body.

3. The semiconductor product according to claim 1, wherein said first region is doped inhomogeneously with a doping density which has a maximum at said ohmic contact layer.

4. The semiconductor product according to claim 1, wherein said first region surrounds said Schottky contact.

5. The semiconductor product according to claim 1, wherein said semiconducting body is divided into an epitaxial layer facing said Schottky contact and a substrate remote from said Schottky contact and doped more heavily than said epitaxial layer.

6. The semiconductor product according to claim 5, including a further ohmic contact contacted connected to said substrate.

7. The semiconductor product according claim 1, wherein said semiconducting body is a crystal made of silicon carbide.

8. The semiconductor product according to claim 1, including a conductive contact reinforcing layer covering said Schottky contact layer.

9. The semiconductor product according to claim 8, wherein said conductive contact reinforcing layer connects said Schottky contact layer to said ohmic contact layer.
